(19) United States
(12) Patent Application Publication
(10) Pub. No.: US 2026/0121381 A1
(43) Pub. Date: Apr. 30, 2026

(54) VERTICAL-CAVITY SURFACE-EMITTING LASER HAVING GRATING STRUCTURE

(71) Applicant: HLJ TECHNOLOGY CO., LTD., Hsinchu County (TW)

(72) Inventors: PO-CHOU PAN, Pingtung County (TW); WEI-WUN JHENG, New Taipei City (TW)

(21) Appl. No.: 19/014,381

(22) Filed: Jan. 9, 2025

(30) Foreign Application Priority Data
Oct. 30, 2024 (TW) 113141384

(51) Int. Cl. H01S 5/183

(52) U.S. Cl. CPC H01S 5/18361; H01S 5/18394

(57) ABSTRACT

A vertical-cavity surface-emitting laser having a grating structure includes a circuit board, a light-emitting composite layer, and the grating structure. The light-emitting composite layer is disposed on the circuit board, and includes a first Bragg reflector, a light-emitting layer, and a second Bragg reflector. The grating structure is disposed on the first Bragg reflector, and includes a contact layer and a protective layer. The contact layer includes a main body and a plurality of protrusions disposed on the main body, and a groove is formed between two adjacent ones of the protrusions. The protective layer is disposed on the contact layer. The protective layer covers each protrusion and each groove, and corresponds in structure to each protrusion and each groove. The protective layer has an undulating surface.

### CROSS-REFERENCE TO RELATED PATENT APPLICATION

This application claims the benefit of priority to Taiwan Patent Application No. 113141384, filed on Oct. 30, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a vertical-cavity surface-emitting laser, and more particularly to a vertical-cavity surface-emitting laser having a grating structure.

### BACKGROUND OF THE DISCLOSURE

Due to having advantages of being small in volume, light in weight, low in costs, and high in energy conversion efficiency, a semiconductor laser is widely applied in electronic products.

In the conventional technology of the semiconductor laser, a vertical-cavity surface-emitting laser (VCSEL) is developed for application in various technical fields that include fiber-optic communication systems, scanning systems of consumer electronics (e.g., iris recognition of a smartphone or a tablet computer), 3D printing, biometric identification and sensing, and laser projection display. As such, it can be observed that the future need for the vertical-cavity surface-emitting laser is considerable.

Therefore, how to provide a vertical-cavity surface-emitting laser having a stable structure and good performance has become one of the important issues to be solved in the relevant industry.

### SUMMARY OF THE DISCLOSURE

In response to the above-referenced technical inadequacy, the present disclosure provides a vertical-cavity surface-emitting laser having a grating structure.

In order to solve the above-mentioned problem, one of the technical aspects adopted by the present disclosure is to provide a vertical-cavity surface-emitting laser having a grating structure, which includes a circuit board, a light-emitting composite layer, a contact layer, an electrode layer, and a protective layer. The light-emitting composite layer is disposed on the circuit board, and includes a first Bragg reflector, a light-emitting layer, and a second Bragg reflector. The first Bragg reflector and the second Bragg reflector are respectively disposed on two sides of the light-emitting layer. The contact layer is disposed on the first Bragg reflector, and has the grating structure. The grating structure includes a main body and a plurality of protrusions disposed on the main body, and one of a plurality of grooves is formed between two adjacent ones of the plurality of protrusions. The electrode layer is disposed on the contact layer, and has a light output aperture. At least one portion of the grating structure is exposed from the light output aperture. The protective layer covers the electrode layer and the grating structure. The protective layer corresponds in shape to each of the plurality of protrusions and each of the plurality of grooves, and the protective layer has an undulating surface.

In one of the possible or preferred embodiments, the protective layer is an aluminum oxide layer, a silicon dioxide layer, a silicon nitride layer, or a magnesium fluoride layer.

In one of the possible or preferred embodiments, a distance between centers of the two adjacent ones of the plurality of protrusions is less than a light-emitting wavelength of the light-emitting composite layer.

In one of the possible or preferred embodiments, a depth of the groove along a vertical direction is greater than 10 nm, and is less than or equal to twice a light-emitting wavelength of the light-emitting composite layer.

In one of the possible or preferred embodiments, a thickness of the contact layer along a vertical direction ranges between 10 nm and 10 μm.

In one of the possible or preferred embodiments, a thickness of the protective layer along a vertical direction is greater than 1 nm, and is less than or equal to 0.4 times a distance between centers of the two adjacent ones of the plurality of protrusions.

In one of the possible or preferred embodiments, along a horizontal direction, a ratio of a width of the groove to a distance between centers of the two adjacent ones of the plurality of protrusions ranges between 0.1 and 0.9.

In one of the possible or preferred embodiments, from a top view, the plurality of protrusions and the plurality of grooves extend along a first direction, the light output aperture defines a center line that passes through a center point of the light output aperture, the center line is parallel to a second direction, and the second direction is orthogonal to the first direction. The center line divides the grating structure that is exposed from the light output aperture into a first portion and a second portion, and the first portion and the second portion are not axially symmetric with respect to the center line.

In one of the possible or preferred embodiments, the first portion and the second portion are projected along a light output direction, and a projected area ratio of the first portion to the second portion is greater than or equal to 10%.

In one of the possible or preferred embodiments, the first Bragg reflector is a P-type Bragg reflector or an N-type Bragg reflector.

Therefore, in the vertical-cavity surface-emitting laser having the grating structure provided by the present disclosure, by virtue of “the contact layer having a grating structure, the grating structure including a main body and a plurality of protrusions disposed on the main body, and one of a plurality of grooves being formed between two adjacent ones of the plurality of protrusions,” “the electrode layer being disposed on the contact layer and having a light output aperture, and at least one portion of the grating structure being exposed from the light output aperture,” and “the protective layer covering the electrode layer and the grating structure, the protective layer corresponding in shape to each of the plurality of protrusions and each of the plurality of grooves, and the protective layer having an undulating surface,” a refractive index difference of the grating structure and an external environment can be maximized, thereby allowing a density of states (DOS) of the vertical-cavity surface-emitting laser having the grating structure to be significantly increased during operation. In this way, a polarization effect of components within the vertical-cavity surface-emitting laser having the grating structure can be enhanced and stabilized.

Furthermore, by virtue of “the plurality of protrusions and the plurality of grooves extending along a first direction, a center line being defined to pass through a center point of the light output aperture, the center line being parallel to a second direction, and the second direction being orthogonal to the first direction” and “the center line dividing the grating structure that is exposed from the light output aperture into a first portion and a second portion, and the first portion and the second portion being not axially symmetric with respect to the center line,” an improved polarization extinction ratio can be achieved (as compared with a structure in which the first portion and the second portion are axial symmetric with respect to the center line).

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view of an appearance of a vertical-cavity surface-emitting laser having a grating structure according to one embodiment of the present disclosure;

FIG. 2 is a schematic side view of the embodiment shown in FIG. 1;

FIG. 3 is an electron microscopy image of the vertical-cavity surface-emitting laser having the grating structure according to one embodiment of the present disclosure;

FIG. 4 is a schematic cross-sectional view of the embodiment shown in FIG. 3; and

FIG. 5 is a schematic top view of the vertical-cavity surface-emitting laser having the grating structure according to one embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

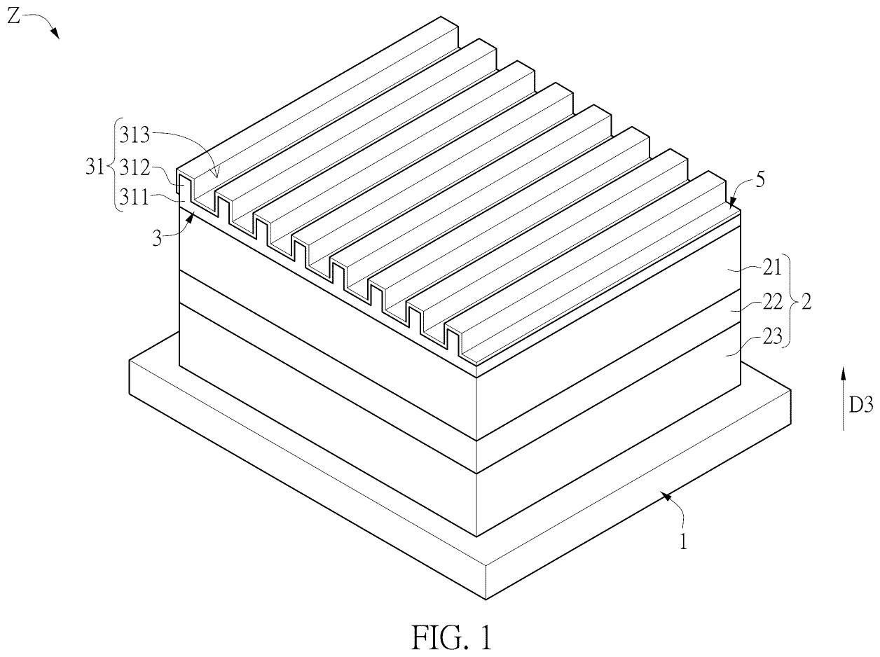

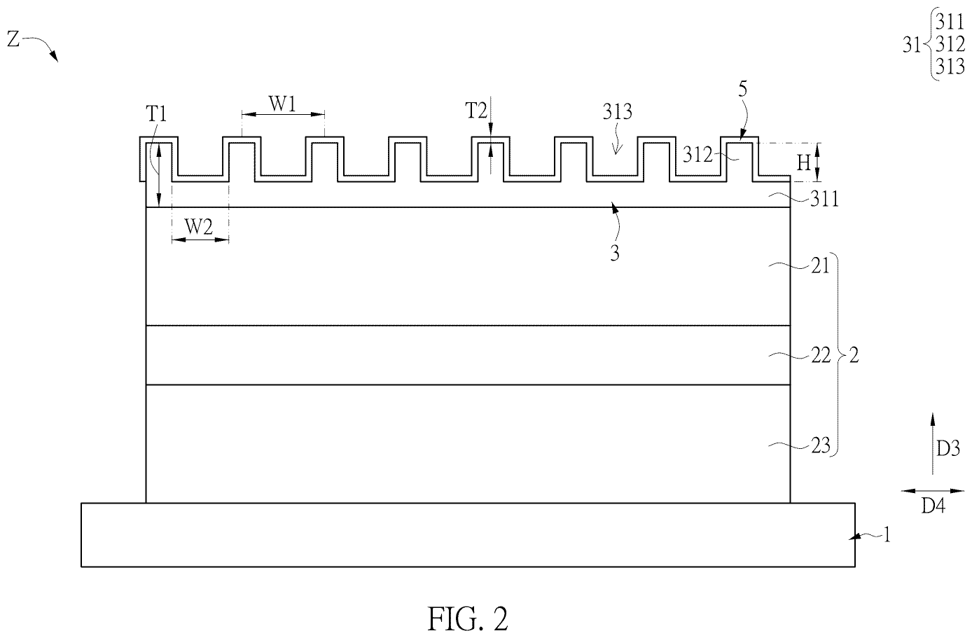

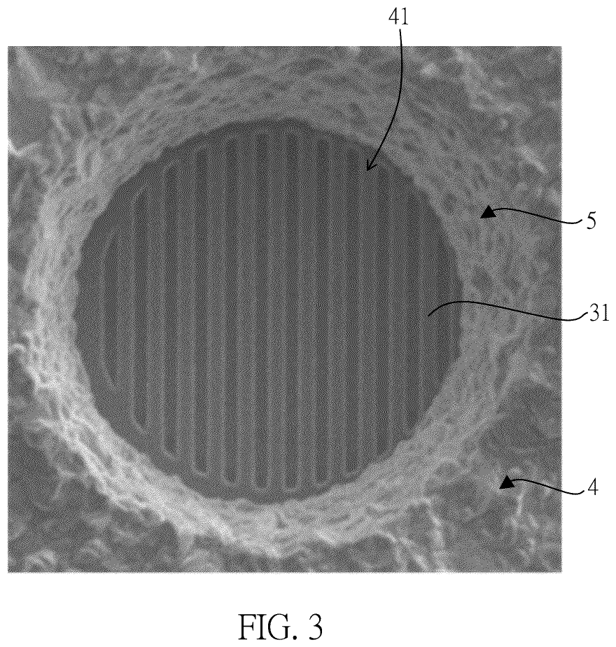

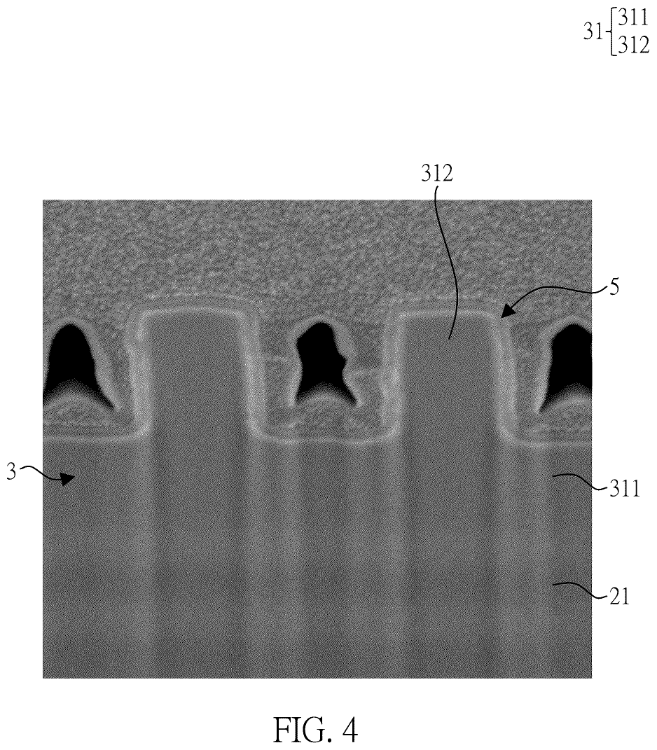

Referring to FIG. 1 to FIG. 4, FIG. 1 is a schematic view of an appearance of a vertical-cavity surface-emitting laser having a grating structure according to one embodiment of the present disclosure, FIG. 2 is a schematic side view of the embodiment shown in FIG. 1, FIG. 3 is an electron microscopy image of the vertical-cavity surface-emitting laser having the grating structure according to one embodiment of the present disclosure, and FIG. 4 is a schematic cross-sectional view of the embodiment shown in FIG. 3.

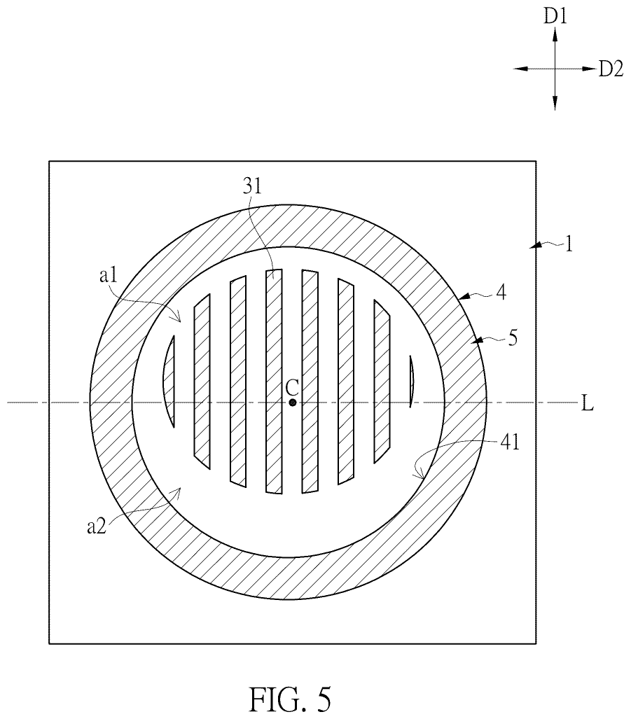

A vertical-cavity surface-emitting laser Z having a grating structure includes a circuit board 1, a light-emitting composite layer 2, a contact layer 3, an electrode layer 4, and a protective layer 5. In the embodiment of FIG. 1 and FIG. 2, the electrode layer 4 is omitted. The light-emitting composite layer 2 is disposed on the circuit board 1, and includes a first Bragg reflector 21, a light-emitting layer 22, and a second Bragg reflector 23. The first Bragg reflector 21 and the second Bragg reflector 23 are disposed on two sides of the light-emitting layer 22, respectively. The contact layer 3 is disposed on the first Bragg reflector 21, and has a grating structure 31. The grating structure 31 includes a main body 311 and a plurality of protrusions 312 disposed on the main body 311. A groove 313 is formed between two adjacent ones of the protrusions 312. As shown in FIG. 3, the electrode layer 4 is disposed on the contact layer 3, and has a light output aperture 41. At least one portion of the grating structure 31 is exposed from the light output aperture 41 (reference can also be made to FIG. 5). Another electrode layer can be disposed on a bottom portion of the circuit board 1. The electrode layer is made of a conductive material (e.g., a metal material), but the present disclosure is not limited thereto. The protective layer 5 covers the electrode layer 4 and the grating structure 31, and corresponds in structure to each protrusion 312 and each groove 313. A surface of the protective layer 5 has an undulating configuration.

The light-emitting layer 22 has an active region and an oxide layer (a current confinement layer, which is not shown in the drawings), and the oxide layer has a confinement aperture. In certain embodiments, the first Bragg reflector 21 is a P-type Bragg reflector or an N-type Bragg reflector, and the second Bragg reflector 23 is a corresponding Bragg reflector. For example, the second Bragg reflector 23 is the N-type Bragg reflector when the first Bragg reflector 21 is the P-type Bragg reflector, and the second Bragg reflector 23 is the P-type Bragg reflector when the first Bragg reflector 21 is the N-type Bragg reflector.

For the grating structure 31 of the contact layer 3, a pattern can be designed by nanoimprint or deep ultraviolet (DUV) lithography. The protrusions 312 and the grooves 313 (i.e., the grating structure 31) are formed on the contact layer 3 by etching, such as ICP (inductively coupled plasma) dry etching. Then, formation of the protective layer 5 is completed by vapor deposition, such as atomic layer deposition (ALD). A semiconductor can be formed by epitaxy, and can be doped or undoped. In certain embodiments, the contact layer 3 is gallium arsenide. In certain embodiments, the protective layer 5 is an oxide layer (which can be, for example but not limited to, an aluminum oxide layer), and can also be a silicon dioxide (SiO₂) layer, a silicon nitride (SiNx) layer, or a magnesium fluoride (MgF₂) layer. Through the configuration of the protective layer 5 (which corresponds to the protrusions 312 and the grooves 313 and has an undulating surface) and a thickness design, a refractive index difference of the contact layer 3 and an external environment (e.g., air) can be maximized, thereby allowing a density of states (DOS) of the vertical-cavity surface-emitting laser having the grating structure to be significantly increased during operation. In this way, a polarization effect of components within the vertical-cavity surface-emitting laser having the grating structure can be enhanced and stabilized.

In certain embodiments, a distance W1 (as shown in FIG. 2) between centers of the two adjacent ones of the protrusions 312 is less than a light-emitting wavelength of the light-emitting composite layer 2. In other embodiments, a depth H of the groove 313 along a vertical direction D3 is greater than 10 nm, and is less than or equal to twice the light-emitting wavelength of the light-emitting composite layer 2. In yet other embodiments, a thickness T1 of the contact layer 3 along the vertical direction D3 ranges between 10 nm and 10 μm. In still other embodiments, a thickness T2 of the protective layer 5 along the vertical direction D3 is greater than 1 nm, and is less than or equal to 0.4 times the distance W1 between the centers of the two adjacent ones of the protrusions 312. Moreover, along a horizontal direction D4, a ratio of a width W2 of the groove 313 to the distance W1 between the centers of the two adjacent ones of the protrusions 312 in certain embodiments ranges between 0.1 and 0.9. At least one of the above-mentioned structural conditions can improve the technical efficacy mentioned previously. In the present disclosure, there is no limitation that all of the above-mentioned structural or light-emitting wavelength conditions need to be satisfied before achieving maximization of the refractive index difference of the contact layer 3 and the external environment, increase in the density of states of the vertical-cavity surface-emitting laser having the grating structure during operation, and enhancement and stabilization of the polarization effect of the components within the vertical-cavity surface-emitting laser having the grating structure.

Reference is made to FIG. 5, which is a schematic top view of the vertical-cavity surface-emitting laser having the grating structure according to one embodiment of the present disclosure. As shown in FIG. 5, from a top view, the protrusions 312 and the grooves 313 extend along a first direction D1, a center line L is defined to pass through a center point C of the light output aperture 41, the center line L is parallel to a second direction D2, and the second direction D2 is orthogonal to the first direction D1. The center line L divides the grating structure 31 that is exposed from the light output aperture 41 into a first portion a1 and a second portion a2, and the first portion a1 and the second portion a2 are not axially symmetric with respect to the center line L. A comparison between this structure and a structure in which the first portion a1 and the second portion a2 are axially symmetric with respect to the center line L shows that the embodiment of FIG. 5 has an improved polarization extinction ratio (PER). In certain embodiments, the polarization extinction ratio ranges approximately between 3 and 4.

Specifically, due to the structure in which the above-mentioned first portion a1 and second portion a2 are not axially symmetric with respect to the center line L, projected areas of the first portion a1 and the second portion a2 when being projected along a light output direction (e.g., the vertical direction D3) differ from one another. In certain embodiments, a projected area ratio can be greater than or equal to 10%.

### Beneficial Effects of the Embodiments

In conclusion, in the vertical-cavity surface-emitting laser having the grating structure provided by the present disclosure, by virtue of “the contact layer having a grating structure, the grating structure including a main body and a plurality of protrusions disposed on the main body, and one of a plurality of grooves being formed between two adjacent ones of the plurality of protrusions,” “the electrode layer being disposed on the contact layer and having a light output aperture, and at least one portion of the grating structure being exposed from the light output aperture,” and “the protective layer covering the electrode layer and the grating structure, the protective layer corresponding in shape to each of the plurality of protrusions and each of the plurality of grooves, and the protective layer having an undulating surface,” a refractive index difference of the grating structure and the external environment can be maximized, thereby allowing the density of states of the vertical-cavity surface-emitting laser having the grating structure to be significantly increased during operation. In this way, the polarization effect of the components within the vertical-cavity surface-emitting laser having the grating structure can be enhanced and stabilized.

Furthermore, by virtue of “the plurality of protrusions and the plurality of grooves extending along a first direction, a center line being defined to pass through a center point of the light output aperture, the center line being parallel to a second direction, and the second direction being orthogonal to the first direction” and “the center line dividing the grating structure that is exposed from the light output aperture into a first portion and a second portion, and the first portion and the second portion being not axially symmetric with respect to the center line,” an improved polarization extinction ratio can be achieved (as compared with a structure in which the first portion and the second portion are axial symmetric with respect to the center line).

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A vertical-cavity surface-emitting laser, comprising:
a circuit board;
a light-emitting composite layer disposed on the circuit board, wherein the light-emitting composite layer includes a first Bragg reflector, a light-emitting layer, and a second Bragg reflector, and the first Bragg reflector and the second Bragg reflector are respectively disposed on two sides of the light-emitting layer;
a contact layer disposed on the first Bragg reflector, wherein the contact layer has a grating structure, the grating structure includes a main body and a plurality of protrusions disposed on the main body, and one of a plurality of grooves is formed between two adjacent ones of the plurality of protrusions;
an electrode layer disposed on the contact layer, wherein the electrode layer has a light output aperture, and at least one portion of the grating structure is exposed from the light output aperture; and
a protective layer covering the electrode layer and the grating structure, wherein the protective layer corresponds in shape to each of the plurality of protrusions and each of the plurality of grooves, and the protective layer has an undulating surface.

2. The vertical-cavity surface-emitting laser according to claim 1, wherein the protective layer is an aluminum oxide layer, a silicon dioxide layer, a silicon nitride layer, or a magnesium fluoride layer.

3. The vertical-cavity surface-emitting laser according to claim 1, wherein a distance between centers of the two adjacent ones of the plurality of protrusions is less than a light-emitting wavelength of the light-emitting composite layer.

4. The vertical-cavity surface-emitting laser according to claim 1, wherein a depth of the groove along a vertical direction is greater than 10 nm, and is less than or equal to twice a light-emitting wavelength of the light-emitting composite layer.

5. The vertical-cavity surface-emitting laser according to claim 1, wherein a thickness of the contact layer along a vertical direction ranges between 10 nm and 10 μm.

6. The vertical-cavity surface-emitting laser according to claim 1, wherein a thickness of the protective layer along a vertical direction is greater than 1 nm, and is less than or equal to 0.4 times a distance between centers of the two adjacent ones of the plurality of protrusions.

7. The vertical-cavity surface-emitting laser according to claim 1, wherein, along a horizontal direction, a ratio of a width of the groove to a distance between centers of the two adjacent ones of the plurality of protrusions ranges between 0.1 and 0.9.

8. The vertical-cavity surface-emitting laser according to claim 1, wherein, from a top view, the plurality of protrusions and the plurality of grooves extend along a first direction, the light output aperture defines a center line that passes through a center point of the light output aperture, the center line is parallel to a second direction, and the second direction is orthogonal to the first direction; wherein the center line divides the grating structure that is exposed from the light output aperture into a first portion and a second portion, and the first portion and the second portion are not axially symmetric with respect to the center line.

9. The vertical-cavity surface-emitting laser according to claim 8, wherein the first portion and the second portion are projected along a light output direction, and a projected area ratio of the first portion to the second portion is greater than or equal to 10%.

10. The vertical-cavity surface-emitting laser according to claim 1, wherein the first Bragg reflector is a P-type Bragg reflector or an N-type Bragg reflector.
